(19) United States
(12) Patent Application Publication
(10) Pub. No.: US 2017/0213952 A1
(43) Pub. Date: Jul. 27, 2017

(54) POWER GENERATOR FOR VEHICLE

(71) Applicant: TOYOTA JIDOSHA KABUSHIKI KAISHA, Toyota-shi (JP)

(72) Inventor: Kazuhiro SUGIMOTO, Susono-shi (JP)

(73) Assignee: TOYOTA JIDOSHA KABUSHIKI KAISHA, Toyota-shi (JP)

(21) Appl. No.: 15/369,047

(22) Filed: Dec. 5, 2016

(30) Foreign Application Priority Data
Jan. 25, 2016 (JP) 2016-011615

(51) Int. Cl. H01L 35/32; H01L 27/16; H01L 35/30

(52) U.S. Cl. CPC H01L 35/32; H01L 35/30; H01L 27/16

(57) ABSTRACT

A power generator includes thermoelectric transducers configured so that the band gap energy of an intrinsic semiconductor part disposed between an n-type semiconductor part and a p-type semiconductor part is lower than each band gap energy of the n-type semiconductor part and the p-type semiconductor part. The power generator is used in a vehicle that includes an exhaust pipe serving as a heat supplier. The thermoelectric transducers are supplied with heat from the exhaust pipe through an insulating member. The thermoelectric transducers are installed in such a manner that a portion of the surface of the intrinsic semiconductor part is in contact with the surface of the insulating member (heat supply surface).

### CROSS-REFERENCE TO RELATED APPLICATION

This application is based on and claims the benefit of Japanese Patent Application No. 2016-011615, filed on Jan. 25, 2016, which is incorporated by reference herein in its entirety.

### BACKGROUND

Technical Field

The present disclosure relates to a power generator for a vehicle, and more particularly to a power generator for a vehicle that incorporates a thermoelectric transducer.

Background Art

There are various thermoelectric transducers based on the Seebeck effect. For such a thermoelectric transducer to produce an electromotive voltage, there needs to be a temperature difference between the two kinds of metals or semiconductors forming the thermoelectric transducer. Thus, power generation using the thermoelectric transducer requires a device that maintains the temperature difference, such as a cooler. WO 2015125823 A1 discloses a semiconductor single crystal that can be used as a thermoelectric transducer capable of generating power without the temperature difference.

Specifically, the semiconductor single crystal disclosed in WO 2015125823 A1 includes an n-type semiconductor part, a p-type semiconductor part, and an intrinsic semiconductor part disposed between the n-type semiconductor part and the p-type semiconductor part, and the band gap energy of the intrinsic semiconductor part is set to be lower than each band gap energy of the n-type semiconductor part and the p-type semiconductor part. If the semiconductor single crystal having this configuration is heated to fall within a predetermined temperature range, electrons in the valence band of the intrinsic semiconductor part is excited into the conduction band, even if there is no temperature difference between the n-type semiconductor part and the p-type semiconductor part. The electrons excited into the conduction band moves to the n-type semiconductor part, which has a lower energy, and the holes formed in the valence band moves to the p-type semiconductor part, which has higher energy. As a result of these movements, the carriers (electron and holes) are unevenly distributed, and the semiconductor single crystal serves as a power generating material with the p-type semiconductor part serving as a positive electrode and the n-type semiconductor part serving as a negative electrode. The semiconductor single crystal having this configuration used as a thermoelectric transducer can generate electric power when the temperature of the thermoelectric transducer is within the predetermined temperature range, even if there is no temperature difference between the n-type semiconductor part and the p-type semiconductor part.

In addition to WO 2015125823 A1, JP 2004-011512A is a patent document which may be related to the present disclosure.

### SUMMARY

To efficiently use the heat emitted by components of a vehicle, such as an automobile, a power generator including the semiconductor single crystal disclosed in WO 2015125823 A1 as a thermoelectric transducer can be installed in various sites in the vehicle. When this kind of power generator is installed, it is favorable to be able to efficiently generate electric power based on the characteristics of the thermoelectric transducer.

The present disclosure has been made to address the problem described above, and an object of the present disclosure is to provide a power generator for a vehicle, which includes a thermoelectric transducer configured so that the band gap energy of an intrinsic semiconductor part disposed between an n-type semiconductor part and a p-type semiconductor part is lower than each band gap energy of the n-type semiconductor part and the p-type semiconductor part, and in which the thermoelectric transducer is mounted on the vehicle in such a manner as to efficiently generate electric power.

A power generator for a vehicle according to the present disclosure includes a thermoelectric transducer including an n-type semiconductor part, a p-type semiconductor part, and an intrinsic semiconductor part disposed between the n-type semiconductor part and the p-type semiconductor part. A band gap energy of the intrinsic semiconductor part is lower than each band gap energy of the n-type semiconductor part and the p-type semiconductor part. The power generator is used in a vehicle that includes a heat supplier configured to supply heat to the thermoelectric transducer. The thermoelectric transducer is supplied with heat from a heat supply surface, which is a surface of the heat supplier or a surface of an intermediate member between the thermoelectric transducer and the heat supplier. The thermoelectric transducer is installed in such a manner that at least a portion of a surface of at least the intrinsic semiconductor part of a surface of the thermoelectric transducer is in contact with the heat supply surface.

The thermoelectric transducer may include a first thermoelectric transducer and a second thermoelectric transducer. The power generator may further include an electrode that electrically connects the first thermoelectric transducer and the second thermoelectric transducer to each other. At least a portion of the surface of at least the intrinsic semiconductor part of the surface of the first thermoelectric transducer may be in contact with a first portion of the heat supply surface. At least a portion of the surface of at least the intrinsic semiconductor part of the surface of the second thermoelectric transducer may be in contact with a second portion of the heat supply surface, which is different from the first portion.

The electrode may connect an end portion of the n-type semiconductor part of the first thermoelectric transducer on a side opposite to the intrinsic semiconductor part and an end portion of the p-type semiconductor part of the second thermoelectric transducer on a side opposite to the intrinsic semiconductor part.

The electrode may include: a positive electrode that connects an end portion of the n-type semiconductor part of the first thermoelectric transducer on a side opposite to the intrinsic semiconductor part and an end portion of the n-type semiconductor part of the second thermoelectric transducer on a side opposite to the intrinsic semiconductor part to each other; and a negative electrode that connects an end portion of the p-type semiconductor part of the first thermoelectric transducer on a side opposite to the intrinsic semiconductor part and an end portion of the p-type semiconductor part of the second thermoelectric transducer on a side opposite to the intrinsic semiconductor part to each other.

The power generator may be configured so that a heat flux received, from the heat supply surface by a surface of the electrode on a side of the heat supply surface is lower than a heat flux received from the heat supply surface by a surface of the intrinsic semiconductor part of each of the first thermoelectric transducer and the second thermoelectric transducer.

The electrode may be installed to face the heat supply surface with an air layer interposed therebetween.

The power generator may further include a heat insulator interposed between the surface of the electrode and the heat supply surface.

The power generator may further include a heat insulator installed between the heat supply surface and an end portion of the n-type semiconductor part of the thermoelectric transducer on a side opposite to the intrinsic semiconductor part or an end portion of the p-type semiconductor part of the thermoelectric transducer on a side opposite to the intrinsic semiconductor part.

The thermoelectric transducer may include a plurality of thermoelectric transducers. The power generator may include the plurality of thermoelectric transducers in a form of a thermoelectric transducer module. The thermoelectric transducer module may include a transducer stack formed by the plurality of thermoelectric transducers electrically connected to each other and a housing that houses the transducer stack. The housing may serve as the intermediate member, or the housing and an insulating member interposed between the housing and the plurality of thermoelectric transducers may serve as the intermediate member. The heat supply surface for at least some of the plurality of thermoelectric transducers forming the transducer stack may be an inner surface of the housing or a surface of the insulating member on a side of the plurality of thermoelectric transducers.

The thermoelectric transducer module may be installed in such a manner that an outer surface of the housing opposite to the inner surface of the housing is in contact with the surface of the heat supplier.

The heat supply surfaces may include a first heat supply surface and a second heat supply surface. Of the surface of the thermoelectric transducer, a first portion of the surface of the intrinsic semiconductor part may be in contact with the first heat supply surface, and a second portion of the surface of the intrinsic semiconductor part is in contact with the second heat supply surface.

The heat supplier may include a plurality of heat suppliers. At least a portion of the surface of at least the intrinsic semiconductor part of the surface of the thermoelectric transducer may be in contact with the heat supply surface of each of the plurality of heat suppliers.

The heat supplier may be an exhaust pipe of an internal combustion engine mounted on the vehicle. In addition, if the heat supplier includes a plurality of heat suppliers, one of the plurality of heat suppliers may be an exhaust pipe of an internal combustion engine mounted on the vehicle.

According to the power generator for a vehicle of the present disclosure, the thermoelectric transducer is configured so that the band gap energy of the intrinsic semiconductor part disposed between the n-type semiconductor part and the p-type semiconductor part is lower than each band gap energy of the n-type semiconductor part and the p-type semiconductor part, and the thermoelectric transducer is installed in such a manner that at least a portion of the surface of at least the intrinsic semiconductor part is in contact with the heat supply surface. If a temperature difference is produced in such a manner that the temperature of the n-type semiconductor part or the p-type semiconductor part having a relatively higher band gap energy is higher than the temperature of the intrinsic semiconductor part, it becomes difficult for the thermoelectric transducer having the configuration described above to efficiently produce an electromotive voltage. According to the installation method according to the power generator, however, the thermoelectric transducer can be installed on the vehicle in such a manner that heat input to the intrinsic semiconductor part is ensured. As a result, the temperature difference in the manner described above is less likely to be produced, and the thermoelectric transducer can efficiently produce the electromotive voltage. Thus, efficient power generation can be achieved.

### BRIEF DESCRIPTION OF THE DRAWINGS

FIG. 1 is a diagram showing an application example of a power generator for a vehicle according to a first embodiment of the present disclosure;

FIG. 2 is a schematic perspective view showing a configuration of each thermoelectric transducer of the power generator shown in FIG. 1;

FIGS. 3A and 3B are conceptual diagrams showing statuses of the band gap energy of the thermoelectric transducer 12 shown in FIG. 2;

FIG. 4 is a graph showing a relation between an electromotive voltage and the temperature of the thermoelectric transducer;

FIG. 5 is a schematic diagram showing a specific configuration of the power generator according to the first embodiment of the present disclosure;

FIGS. 6A and 6B are diagrams for illustrating an advantage of the method of installing the thermoelectric transducer according to the first embodiment;

FIGS. 7A and 7B are diagrams for illustrating an advantage of the manner of stacking of the thermoelectric transducers according to the first embodiment;

FIG. 8 is a schematic perspective view showing an overall configuration of a power generator for a vehicle according to a second embodiment of the present disclosure;

FIG. 9 is a partial perspective view showing an internal structure of a thermoelectric transducer module shown in FIG. 8;

FIG. 10 is a cross-sectional view of a thermoelectric transducer module and an exhaust pipe taken along the line A-A in FIG. 8;

FIGS. 11A and 11B are diagrams for illustrating an advantage of the method of installing the thermoelectric transducer according to the second embodiment by focusing on an individual thermoelectric transducer;

FIGS. 12A and 12B are diagrams for illustrating an advantage of the manner of stacking of the thermoelectric transducers according to the second embodiment;

FIG. 13 is a schematic perspective view showing an overall configuration of a power generator for a vehicle according to a third embodiment of the present disclosure;

FIGS. 14A and 14B are diagrams for illustrating an advantage of the arrangement of electrodes according to the third embodiment;

FIG. 15 is a diagram for illustrating an arrangement of an electrode in a power generator for a vehicle according to a fourth embodiment of the present disclosure;

FIG. 16 is a schematic diagram showing an overall configuration of a power generator 60 for a vehicle according to a fifth embodiment of the present disclosure;

FIGS. 17A and 17B are diagrams for illustrating an advantage of the arrangement of an electrode according to the fifth embodiment;

FIG. 18 is a diagram for illustrating an arrangement of an electrode in a power generator for a vehicle according to a sixth embodiment of the present disclosure;

FIG. 19 is a diagram for illustrating another method of installing the thermoelectric transducer shown in FIG. 2;

FIG. 20 is a diagram for illustrating another method of installing the thermoelectric transducer shown in FIG. 2;

FIGS. 21A and 21B are diagrams for illustrating another method of installing the thermoelectric transducer shown in FIG. 2;

FIGS. 22A and 22B are diagrams for illustrating another manner of stacking of the thermoelectric transducers shown in FIG. 2; and

FIG. 23 is a diagram for illustrating another method of installing the thermoelectric transducer shown in FIG. 2.

### DETAILED DESCRIPTION

In the following, embodiments of the present disclosure will be described with reference to the drawings. In the drawings, the same reference numerals denote the same or similar components.

### First Embodiment

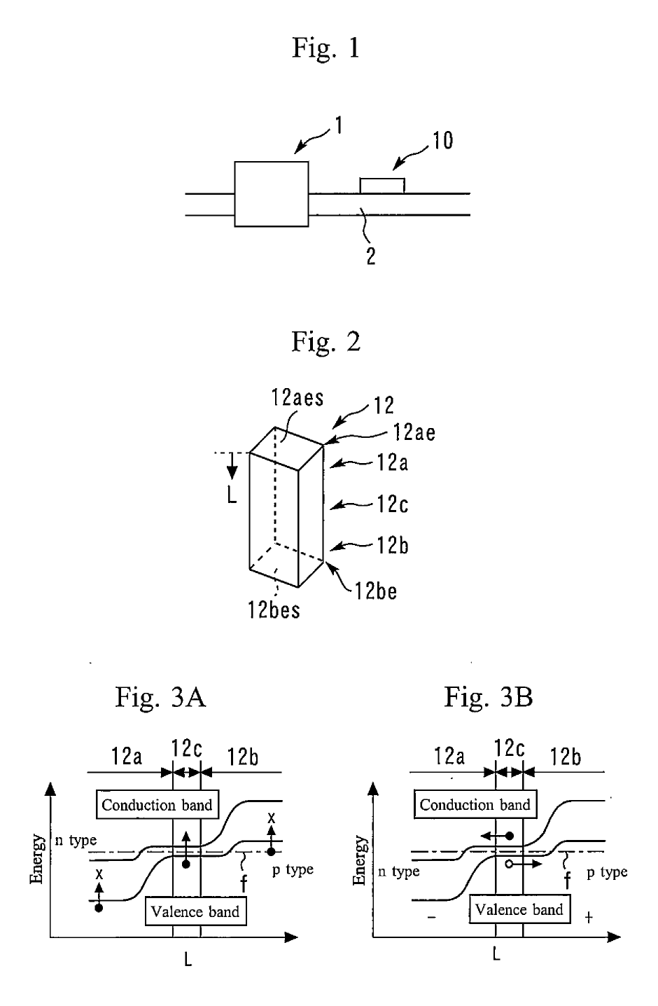

First, with reference to FIGS. 1 to 7, a first embodiment of the present disclosure will be described. FIG. 1 is a diagram showing an application example of a power generator 10 for a vehicle according to the first embodiment of the present disclosure. FIG. 2 is a schematic perspective view showing a configuration of each thermoelectric transducer 12 of the power generator 10 shown in FIG. 1.

### [Installation Site of Power Generator in Vehicle]

The installation site of the power generator 10 according to the present embodiment is not particularly limited. For example, as shown in FIG. 1, the power generator 10 is installed on an exhaust pipe 2, in which exhaust gas from an internal combustion engine 1 mounted on a vehicle flows. In the example shown in FIG. 1, heat of the exhaust gas flowing in the exhaust pipe 2 is supplied to each of thermoelectric transducers 12 via the exhaust pipe 2. Thus, in this example, the exhaust pipe 2 serves as a “heat supplier” according to the present disclosure. Examples of the heat supplier other than the exhaust pipe 2 that is a component of the vehicle and supplies heat to the thermoelectric transducer 12 include a cylinder block and a cylinder head of the internal combustion engine 1, a cooling water hose in which engine cooling water for cooling the internal combustion engine 1 flows, a radiator for cooling the engine cooling water, a transmission associated with the internal combustion engine, and a battery that accumulates electric power used by the vehicle. In addition, the temperature of the heat supplier when supplying heat is higher than the temperature of the ambient atmosphere (atmospheric air, in the present embodiment) of the thermoelectric transducer 12. The power generator 10 according to the present embodiment includes a transducer stack 14 formed by a plurality of thermoelectric transducers 12 electrically connected to each other, although details of the configuration of the power generator 10 will be described later with reference to FIG. 5.

### [Configuration of Thermoelectric Transducer]

In the example shown in FIG. 2, the thermoelectric transducer 12 has the shape of a prism. The thermoelectric transducer 12 has an n-type semiconductor part 12a at one end and a p-type semiconductor part 12b at the other end. The thermoelectric transducer 12 further has an intrinsic semiconductor part 12c between the n-type semiconductor part 12a and the p-type semiconductor part 12b.

FIGS. 3A and 3B are conceptual diagrams showing statuses of the band gap energy of the thermoelectric transducer 12 shown in FIG. 2. In FIGS. 3A and 3B, the vertical axes indicate the energy of an electron, and the horizontal axes indicate the distance L (see FIG. 2) from an end face 12aes of the thermoelectric transducer 12 on the side of the n-type semiconductor part 12a.

As shown in FIGS. 3A and 3B, in the n-type semiconductor part 12a, the Fermi level f is in the conduction band, and in the p-type semiconductor part 12b, the Fermi level f is in the valence band. In the intrinsic semiconductor part 12c, the Fermi level f is at the middle of the forbidden band existing between the conduction band and the valence band. The band gap energy corresponds to the difference in energy between the uppermost part of the valence band and the lowermost part of the conduction band. As can be seen from these drawings, the band gap energy of the intrinsic semiconductor part 12c of the thermoelectric transducer 12 is lower than the band gap energies of the n-type semiconductor part 12a and the p-type semiconductor part 12b. Note that the length ratio between the n-type semiconductor part 12a, the p-type semiconductor part 12b and the intrinsic semiconductor part 12c shown in FIGS. 3A and 3B is just an example, and the ratio can vary depending on how the thermoelectric transducer (semiconductor single crystal) 12 is formed. The band gap energy of the n-type semiconductor part 12a, the p-type semiconductor part 12b and the intrinsic semiconductor part 12c can be measured in inverse photoelectron spectroscopy, for example.

The thermoelectric transducer (semiconductor single crystal) 12 having the characteristics described above (that is, the band gap energy of the intrinsic semiconductor part 12c is lower than the band gap energies of the n-type semiconductor part 12a and the p-type semiconductor part 12b) can be made of a clathrate compound (inclusion compound), for example. As an example of the clathrate compound, a silicon clathrate Ba₈Au₈Si₃₈ may be used.

The thermoelectric transducer 12 according to the present embodiment can be manufactured in any method, as far as the method can produce the thermoelectric transducer 12 having the characteristics described above. If the thermoelectric transducer 12 is made of, for example, the silicon clathrate Ba₈Au₈Si₃₈, the manufacturing method described in detail in International Publication No. WO 2015125823 A1 can be used, for example. The manufacturing method can be summarized as follows. That is, Ba powder, Au powder and Si powder are weighed in the ratio (molar ratio) of 8:8:38. The weighed powders are melted together by arc melting. The melt is then cooled to form an ingot of the silicon clathrate Ba₈Au₈Si₃₈. The ingot of the silicon clathrate Ba₈Au₈Si₃₈ prepared in this way is crushed into grains. The grains of the silicon clathrate Ba₈Au₈Si₃₈ are melted in a crucible in the Czochralski method, thereby forming a single crystal of the silicon clathrate Ba₈Au₈Si₃₈. The thermoelectric transducer 12 shown in FIG. 2 is provided by cutting the single crystal of the silicon clathrate Ba₈Au₈Si₃₈ prepared in this way into the shape of a prism (more specifically, the shape of a rectangular parallelepiped). The shape of the thermoelectric transducer is not limited to the rectangular parallelepiped, and the thermoelectric transducer may have any shape provided by cutting the single crystal into a desired shape, such as a cube or a column.

### [Principle of Power Generation]

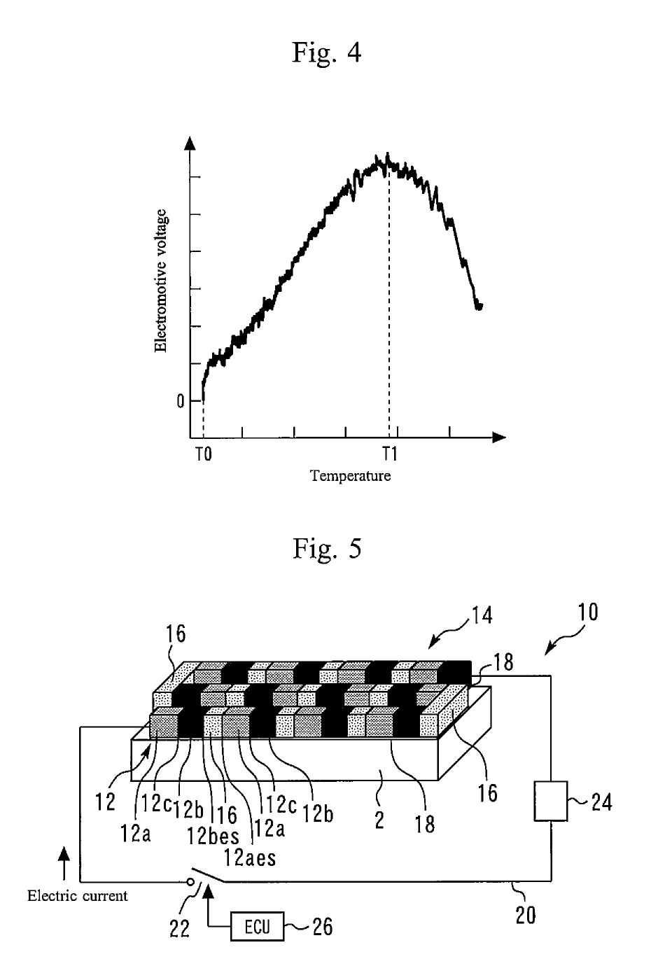

FIG. 3A is a conceptual diagram showing a status of thermal excitation of the thermoelectric transducer 12 when the thermoelectric transducer 12 is heated to a predetermined temperature. If the thermoelectric transducer 12 is heated to a temperature T0 (see FIG. 4 described later) or higher, electrons (shown by black dots) in the valence band are thermally excited into the conduction band, as shown in FIG. 3A. More specifically, if heat is supplied and energy exceeding the band gap energy is thereby supplied to an electron located in an uppermost part of the valence band, the electron is excited into the conduction band. In the process where the temperature of the thermoelectric transducer 12 increases, a condition can occur in which such thermal excitation of electrons occurs only in the intrinsic semiconductor part 12c, which has a relatively low band gap energy. FIG. 3A shows a status of the thermoelectric transducer 12 in which the thermoelectric transducer 12 is heated to a predetermined temperature (such as the temperature T0) that can allow such a condition to occur. In this status, no electrons are thermally excited in the n-type semiconductor part 12a and the p-type semiconductor part 12b, which have a relatively higher band gap energy.

FIG. 3B is a conceptual diagram showing movement of an electron (shown by the black dot) and a hole (shown by a white dot) when the thermoelectric transducer 12 is heated to the predetermined temperature described above. As shown in FIG. 3B, electrons excited into the conduction band move toward a part of lower energy, that is, toward the n-type semiconductor part 12a. On the other hand, holes formed in the valence band as a result of the electrons being excited move toward a part of higher energy, that is, toward the p-type semiconductor part 12b. The carriers are unevenly distributed in this way, so that the n-type semiconductor part 12a is negatively charged, and the p-type semiconductor part 12b is positively charged, and therefore, an electromotive force occurs between the n-type semiconductor part 12a and the p-type semiconductor part 12b. Thus, the thermoelectric transducer 12 can generate power even if there is no temperature difference between the n-type semiconductor part 12a and the p-type semiconductor part 12b. This principle of power generation differs from the Seebeck effect, which produces an electromotive force based on a temperature difference. The power generator 10 using the thermoelectric transducer 12 requires no temperature difference and therefore a cooling part that provides the temperature difference and therefore can be simplified in configuration.

FIG. 4 is a graph showing a relation between an electromotive voltage and the temperature of the thermoelectric transducer 12. The term “electromotive voltage” of the thermoelectric transducer 12 used herein refers to the potential difference between an end portion of the thermoelectric transducer 12 on the side of the p-type semiconductor part 12b serving as a positive electrode and an end portion of the thermoelectric transducer 12 on the side of the n-type semiconductor part 12a serving as a negative electrode. More specifically, the relation shown in FIG. 4 shows temperature characteristics of the electromotive voltage produced when the thermoelectric transducer 12 is heated in such a manner that no temperature difference is produced between the n-type semiconductor part 12a and the p-type semiconductor part 12b. Note that the temperature range in which the electromotive voltage is produced differs depending on the composition of the thermoelectric transducer.

As shown in FIG. 4, the electromotive voltage is produced when the thermoelectric transducer 12 is heated to the temperature T0 or higher. More specifically, as the temperature of the thermoelectric transducer 12 increases, the electromotive voltage also increases. A possible reason why the electromotive voltage increases as the temperature increases as shown in FIG. 4 is that, as the amount of heat supplied increases, the number of electrons and holes that can be excited in the intrinsic semiconductor part 12c, which has a relatively low band gap energy, increases. As shown in FIG. 4, the electromotive voltage reaches a peak value at a certain temperature T1 and decreases as the thermoelectric transducer 12 is further heated beyond the temperature T1. A possible reason for this is that, as the temperature of the thermoelectric transducer 12 increases, not only electrons and holes in the intrinsic semiconductor part 12c but also electrons and holes in the n-type semiconductor part 12a and the p-type semiconductor part 12b are thermally excited.

### [Method of Installing Thermoelectric Transducer (Transducer Stack) on Exhaust Pipe and Overall Configuration of Power Generator]

As can be seen from FIG. 4 described above, power generation by using the thermoelectric transducer 12 is possible if the temperature of the thermoelectric transducer 12 falls within a predetermined range. More favorably, efficient power generation is possible if the temperature of the thermoelectric transducer 12 is close to the temperature T1 at which the peak electromotive voltage is achieved. Thus, to achieve efficient power generation using the thermoelectric transducers 12 on the vehicle, a heat supplier, which can supply heat to the thermoelectric transducers 12 so that the temperature of each of the thermoelectric transducers 12 approaches a temperature suitable for power generation, is selected from among components of the vehicle, and the thermoelectric transducers 12 are installed on the selected heat supplier. More specifically, the temperature of the exhaust gas in the exhaust pipe 2 decreases as it flows downstream, and therefore, the wall temperature of the exhaust pipe 2 is lower in downstream parts of the exhaust pipe 2 than in upstream parts. When the exhaust pipe 2 is used as the heat supplier as in the present embodiment, the installation site of the thermoelectric transducer 12 on the exhaust pipe 2 along the direction of flow of the exhaust gas is determined so that a heat source that allows efficient power generation is provided.

(Issue with Efficient Power Generation)

As described above, the thermoelectric transducer 12 is configured to produce an electromotive voltage as a result of the movement of electrons and holes caused by the electrons in the intrinsic semiconductor part 12c being thermally excited when the thermoelectric transducer 12 is supplied with heat from the heat supplier. If a temperature difference is produced in the thermoelectric transducer 12 in such a manner that the temperature of the intrinsic semiconductor part 12c is higher than the temperature of the n-type semiconductor part 12a and the p-type semiconductor part 12b, thermal excitation of electrons in the intrinsic semiconductor part 12c is promoted compared with thermal excitation of electrons in the n-type semiconductor part 12a and the p-type semiconductor part 12b. This is favorable, rather than an issue. However, depending on the installation of the thermoelectric transducer 12, a temperature difference may be produced in such a manner that the temperature of one or both of the n-type semiconductor part 12a and the p-type semiconductor part 12b is higher than the temperature of the intrinsic semiconductor part 12c. As the temperature difference in this manner increases, electrons are more easily thermally excited in the one or both of the n-type semiconductor part 12a and the p-type semiconductor part 12b. This may make it harder for the thermoelectric transducer 12 to produce the electromotive voltage. To achieve efficient power generation using the thermoelectric transducers 12, it is useful to prevent occurrence of the temperature difference in the latter manner. To this end, each of the thermoelectric transducers 12 (transducer stack 14) is favorably installed on the heat supplier in such a manner as to ensure heat input to the intrinsic semiconductor part 12c.

### (Method of Installing Thermoelectric Transducer (Transducer Stack) According to First Embodiment)

In view of the above description, according to the present embodiment, the transducer stack 14, which is a stack of thermoelectric transducers 12, is installed on an outer surface of the exhaust pipe 2 in the arrangement shown in FIG. 5 described below.

FIG. 5 is a schematic diagram showing a specific configuration of the power generator 10 according to the first embodiment of the present disclosure. In FIG. 5 and other drawings, for the sake of clarity of the arrangement of the thermoelectric transducers 12, the n-type semiconductor part 12a and the p-type semiconductor part 12b of the thermoelectric transducer 12 are distinguished by color. The intrinsic semiconductor part 12c between the n-type semiconductor part 12a and the p-type semiconductor part 12b lies around the boundary between the parts 12a and 12b. In the example shown in FIG. 5, the transducer stack 14 is installed on a flat part of the exhaust pipe 2. However, the transducer stack 14 may be installed in conformity to the curved outer surface of a cylindrical exhaust pipe 2.

As shown in FIG. 5, in the transducer stack 14, adjacent thermoelectric transducers 12 are connected in series with each other with an electrode 16 interposed therebetween. That is, the transducer stack 14 includes the thermoelectric transducers 12 and the electrodes 16. The electrode 16 may be made of a metal material, such as copper, that has low electrical resistance. According to the principle of power generation of the thermoelectric transducer 12 described above, the p-type semiconductor part 12b serves as a positive electrode, and the n-type semiconductor part 12a serves as a negative electrode. Therefore, an electric current caused by the electromotive force produced by power generation flows from the p-type part to the n-type part. In the present embodiment, in order to ensure that the electric current smoothly flows while maximizing the potential difference between the opposite ends of the electrode 16, the electrode 16 is configured to connect an end portion 12ae (see FIG. 2) of the n-type semiconductor part 12a on the opposite side to the intrinsic semiconductor part 12c of one thermoelectric transducer 12 (which corresponds to a “first thermoelectric transducer” according to the present disclosure) and an end portion 12be (see FIG. 2) of the p-type semiconductor part 12b on the opposite side to the intrinsic semiconductor part 12c of another thermoelectric transducer 12 (which corresponds to a “second thermoelectric transducer” according to the present disclosure) to each other. In other words, the electrode 16 is configured to connect parts having the highest band gap energy to each other.

More specifically, the surface of the end portion 12ae of the n-type semiconductor part 12a includes an end face 12aes and a portion of the side surface of the n-type semiconductor part 12a that is close to the end face 12aes. Similarly, the surface of the end portion 12be of the p-type semiconductor part 12b includes an end face 12bes and a portion of the side surface of the p-type semiconductor part 12b that is close to the end face 12bes. In the example shown in FIG. 5, the electrode 16 connects the end face 12aes and the end face 12bes to each other. However, according to the present disclosure, any electrode that connects the end portions of adjacent thermoelectric transducers (the end portion of the n-type semiconductor part on the opposite side to the intrinsic semiconductor part and the end portion of the p-type semiconductor part on the opposite side to the intrinsic semiconductor part) to each other can be used. Thus, as an alternative to the example described above, the electrode 16 may be configured to connect the portion of the side surface of the n-type semiconductor part 12a that is close to the end face 12aes and the portion of the side surface of the p-type semiconductor part 12b that is close to the end face 12bes to each other.

The way of stacking of the thermoelectric transducers 12 is not particularly limited. In the example shown in FIG. 5, the transducer stack 14 is provided with the thermoelectric transducers 12 stacked in series with each other in a serpentine form. With the transducer stack 14, by appropriately determining the number of thermoelectric transducers 12 stacked, any desired level of electromotive voltage can be produced under the temperature condition of the thermoelectric transducers 12 expected from the heat supply from the exhaust pipe 2.

The power generator 10 according to the present embodiment is characterized in that each thermoelectric transducer 12 forming the transducer stack 14 is installed on the exhaust pipe 2 in the manner described below. That is, as shown in FIG. 5, each thermoelectric transducer 12 is installed with a portion of the surface of the intrinsic semiconductor part 12c in contact with the surface (more specifically, outer surface) of the exhaust pipe 2 with an insulating member 18 interposed therebetween. In the example of the shape of the thermoelectric transducer 12 shown in FIG. 5, the portion of the surface of the intrinsic semiconductor part 12c is a surface of the intrinsic semiconductor part 12c included in the side surface of the thermoelectric transducer 12 facing the exhaust pipe 2 (insulating member 18).

The insulating member 18 is provided to suppress a leakage of the electric current from the thermoelectric transducer 12 to the exhaust pipe 2 (metal member). Thus, the insulating member 18 is interposed not only between the thermoelectric transducer 12 and the exhaust pipe 2 but also between the electrode 16 and the exhaust pipe 2. The power generator 10 is required to transfer the heat of the exhaust gas (from the internal combustion engine 1), which is a heat source, from the exhaust pipe 2, which is a heat supplier, to each thermoelectric transducer 12 through the insulating member 18. Therefore, the insulating member 18 is made of a material that has a higher electrical resistance than that of the electrode 16 and high thermal conductivity. Such a material is silicon nitride, aluminum nitride, aluminum oxide, or boron nitride, for example.

In the configuration shown in FIG. 5, the insulating member 18 interposed between each thermoelectric transducer 12 and the exhaust pipe 2 corresponds to an “intermediate member” according to the present disclosure. And the surface of the insulating member 18 on the side of the thermoelectric transducer 12 corresponds to a “heat supply surface” according to the present disclosure. If the surface of the heat supplier is in direct contact with the thermoelectric transducer, the surface of the heat supplier corresponds to the “heat supply surface” according to the present disclosure.

Furthermore, each thermoelectric transducer 12 according to the present embodiment is installed in such a manner that a portion of the surface of the intrinsic semiconductor part 12c is in contact with the heat supply surface with the entire side surface of the thermoelectric transducer 12 facing the exhaust pipe 2 (more specifically, insulating member 18) in contact with the surface of the insulating member 18 (that is, heat supply surface). The aforementioned entire side surface includes not only the side surface of the intrinsic semiconductor part 12c but also the side surfaces of the n-type semiconductor part 12a and the p-type semiconductor part 12b.

### (Overall Configuration of Power Generator)

The power generator 10 is provided with an electrical circuit 20 that is configured to connect the opposite ends of the transducer stack 14 by conductive wires. The electrical circuit 20 is opened and closed with a switch 22. Electrical equipment (such as a light) 24 mounted on the vehicle is connected to the electrical circuit 20. The switch 22 is opened and closed under the control of an electronic control unit (ECU) 26 mounted on the vehicle.

With the power generator 10 configured as described above, during activation of the vehicle system, the transducer stack 14 is enabled to generate power by closing the switch 22 when the temperature of the thermoelectric transducers 12 reaches a temperature suitable for power generation as a result of heat from the exhaust gas being supplied to the thermoelectric transducers 12 via the exhaust pipe 2 and the insulating member 18. In the present embodiment, the heat source is the exhaust gas, so that the exhaust heat of the internal combustion engine 1 can be recovered by the power generation. In addition, the electric power obtained by the power generation by the transducer stack 14 can be supplied to the electrical equipment 24. The switch 22 may be replaced with a variable resistor. In this example, the electric power supplied from the transducer stack 14 to the electrical equipment 24 can be controlled in more detail by adjusting the resistance of the variable resistor. Vehicle equipment that receives the electric power is not limited to the electrical equipment 24, and a battery that accumulates electric power may be connected to the electrical circuit 20 instead of or in addition to the electrical equipment 24, for example.

Although not shown in FIG. 5, the transducer stack 14 is covered with a protective cover. In addition, the transducer stack 14 is fixed to the exhaust pipe 2 with an attachment not shown in the drawing.

### [Advantage of Method of Installing Thermoelectric Transducer (Transducer Stack) According to First Embodiment]

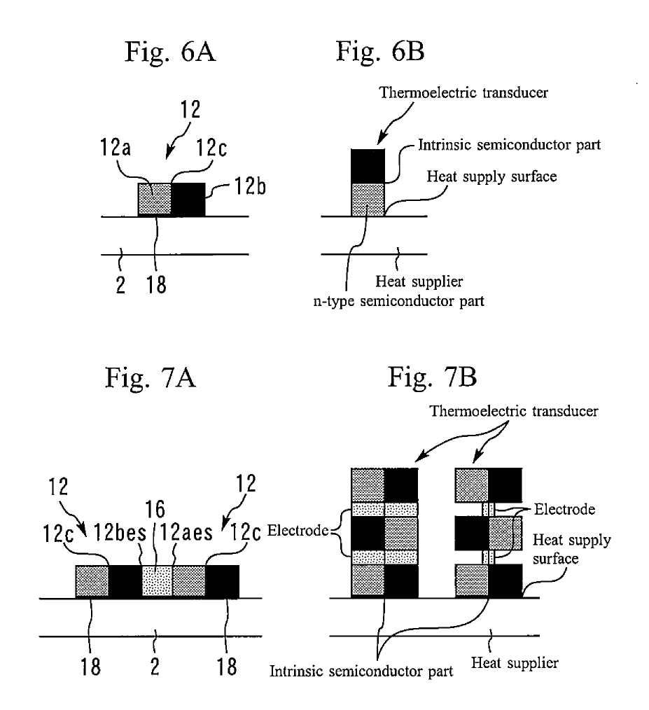

FIGS. 6A and 6B are diagrams for illustrating an advantage of the method of installing the thermoelectric transducer 12 according to the first embodiment. FIG. 6A shows the thermoelectric transducer 12 installed in the method according to the present embodiment, as with the configuration shown in FIG. 5. FIG. 6B shows the thermoelectric transducer installed in a method other than the method according to the present embodiment. More specifically, in the installation method shown in FIG. 6B, the thermoelectric transducer is installed on the heat supplier in such a manner that the end face of the n-type semiconductor part having the highest band gap energy is in contact with the heat supply surface, rather than the surface of the intrinsic semiconductor part being in contact with the heat supply surface.

If the thermoelectric transducer is installed as shown in FIG. 6B, more heat is supplied to the n-type semiconductor part than to the intrinsic semiconductor part. As a result, a temperature difference is produced in such a manner that the temperature of the intrinsic semiconductor part is lower than the temperature of the n-type semiconductor part. Thus, it is difficult to efficiently provide an electromotive voltage of the thermoelectric transducer as described above. To the contrary, according to the installation method according to the present embodiment shown in FIG. 6A, since the surface of the intrinsic semiconductor part 12c is in contact with the heat supply surface (surface of the insulating member 18), heat can be reliably input to the intrinsic semiconductor part 12c having a relatively low band gap energy. Thus, a temperature difference is less likely to be produced in such a manner that the temperature of the n-type semiconductor part 12a or the p-type semiconductor part 12b having a relatively high band gap energy is higher than the temperature of the intrinsic semiconductor part 12c, so that the electromotive voltage of the thermoelectric transducer 12 can be efficiently provided. In addition, since heat can be reliably input to the intrinsic semiconductor part 12c, the intrinsic semiconductor part 12c can be more likely to be supplied with as much heat from the heat supplier as possible even when the amount of heat supplied from the heat supplier is less than the ideal amount.

Next, FIGS. 7A and 7B are diagrams for illustrating an advantage of the manner of stacking of the thermoelectric transducers 12 according to the first embodiment. FIG. 7A shows the thermoelectric transducers 12 stacked in the manner according to the present embodiment, as with the configuration shown in FIG. 5. FIG. 7B shows thermoelectric transducers stacked in another manner. More specifically, in both of the left and right configurations according to the stacking manner shown in FIG. 7B, the surface of the intrinsic semiconductor part of the lowermost thermoelectric transducer is in direct contact with the heat supply surface, and any other thermoelectric transducers have one or more thermoelectric transducers and electrodes placed below it between itself and the heat supply surface. In these configurations, the electrodes are disposed on the intrinsic semiconductor parts having a relatively low band gap energy.

If the thermoelectric transducers are stacked in the manner shown in FIG. 7B, the heat from the exhaust gas (heat source) is inevitably supplied to the thermoelectric transducers other than the lowermost thermoelectric transducer through the other thermoelectric transducers and the electrodes. To the contrary, in the stacking manner according to the present embodiment shown in FIG. 7A, a portion of the surface of the intrinsic semiconductor part 12c of each thermoelectric transducer 12 of the transducer stack 14 is in contact with a different portion of the heat supply surface (surface of the insulating member 18) (the portion corresponds to a “first portion of the heat supply surface” or a “second portion of the heat supply surface” according to the present disclosure). With such a configuration, unlike each of the configurations shown in FIG. 7B, the surfaces of the intrinsic semiconductor parts 12c of all the thermoelectric transducers 12 forming the transducer stack 14 are in contact with the heat supply surface without any other thermoelectric transducer 12 interposed therebetween. As a result, the intrinsic semiconductor part 12c of each individual thermoelectric transducer 12 can receive an approximately equal heat flux (amount of heat passing through a unit area per unit time) from the heat supply surface.

In the stacking manner according to the present embodiment shown in FIG. 7A, the electrode 16 is configured to connect the end face 12aes of the n-type semiconductor part 12a of one thermoelectric transducer 12 and the end face 12bes of the p-type semiconductor part 12b of another thermoelectric transducer 12 to each other. Since the electrodes 16 are disposed to electrically connect the parts having the highest band gap energy to each other, the electromotive voltage can be efficiently provided, and heat can be reliably input to each intrinsic semiconductor part 12c.

### Second Embodiment

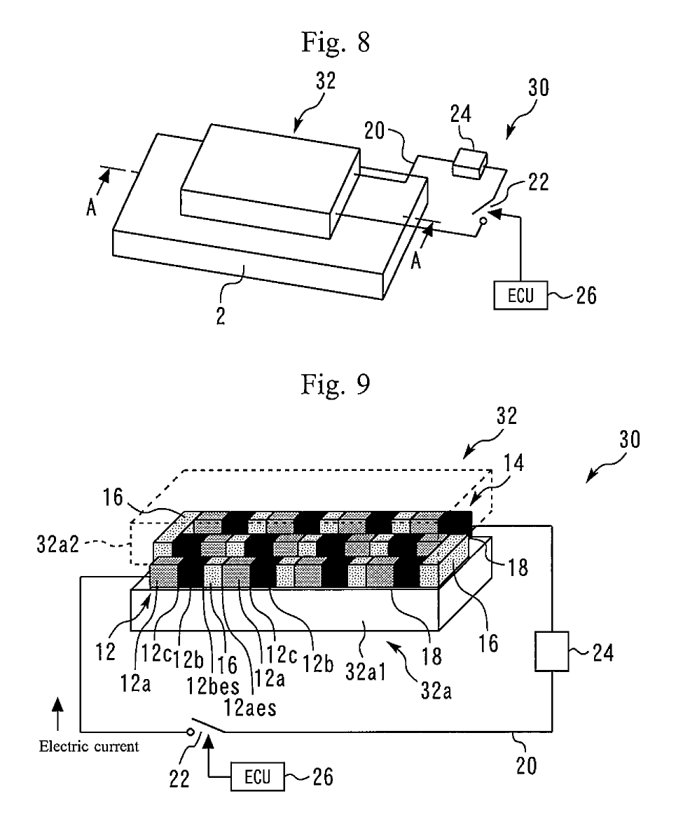

Next, with reference to FIGS. 8 to 12, a second embodiment of the present disclosure will be described.

FIG. 8 is a schematic perspective view showing an overall configuration of a power generator 30 for a vehicle according to the second embodiment of the present disclosure. The power generator 30 according to the present embodiment includes a plurality of thermoelectric transducers 12 as components of a thermoelectric transducer module 32. In the present embodiment, as in the first embodiment, the exhaust pipe 2 is used as an example of the heat supplier that supplies heat to the thermoelectric transducers 12. The thermoelectric transducer module 32 is installed on the exhaust pipe 2. In the following, a method of installing the thermoelectric transducer module 32 will be described in more details.

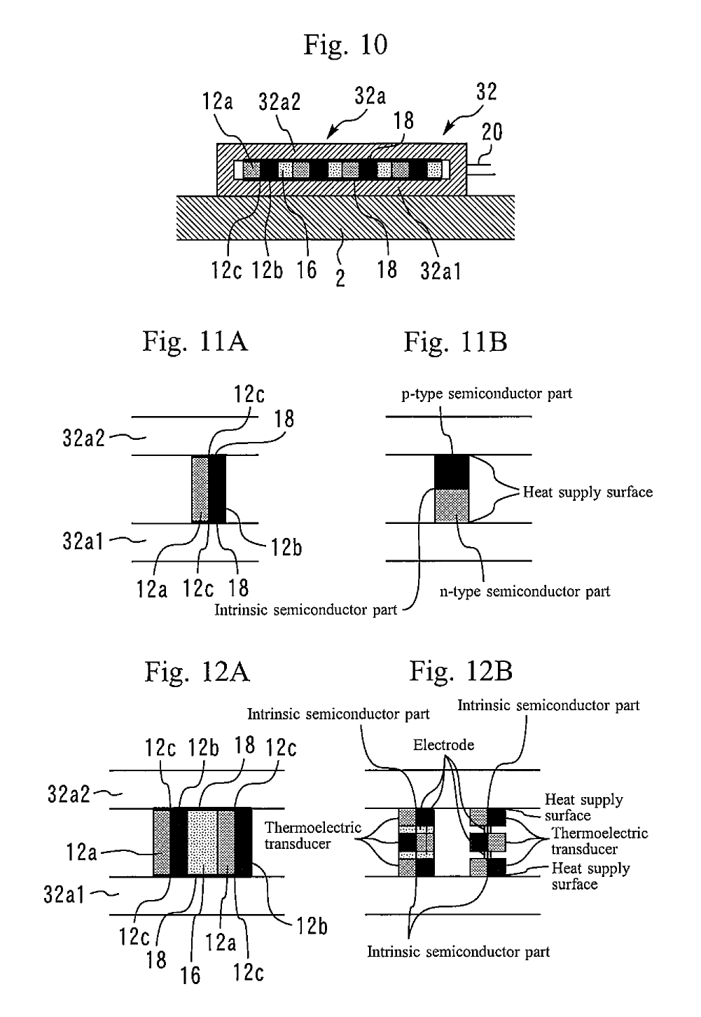

FIG. 9 is a partial perspective view showing an internal structure of the thermoelectric transducer module 32 shown in FIG. 8. FIG. 10 is a cross-sectional view of the thermoelectric transducer module 32 and the exhaust pipe 2 taken along the line A-A in FIG. 8. As shown in these drawings, the thermoelectric transducer module 32 includes the transducer stack 14 formed by a stack of a plurality of thermoelectric transducers 12 and a housing 32a that houses the transducer stack 14. The housing 32a is formed to surround the transducer stack 14. The housing 32a is attached to a flat part of the exhaust pipe 2 with an attachment not shown. The housing 32a is favorably made of a material having a high thermal conductivity and, for example, can be made of a metal, such as aluminum.

The housing 32a has a first wall part 32a1 that faces the exhaust pipe 2 when the thermoelectric transducer module 32 is installed. The first wall part 32a1 is shaped to conform to the outer surface (which is flat in an example of the present embodiment) of the exhaust pipe 2. Once the thermoelectric transducer module 32 is installed on the exhaust pipe 2, the outer surface of the first wall part 32a1 is in direct contact with the outer surface of the exhaust pipe 2. The transducer stack 14 is provided with one side surface thereof facing an inner surface of the first wall part 32a1 with the insulating member 18 interposed therebetween.

The housing 32a has a second wall part 32a2 having an inner surface opposed to the inner surface of the first wall part 32a1. The transducer stack 14 is disposed with a side surface thereof opposite to the above-described one side surface facing the first wall part 32a1 facing the second wall part 32a2 with the insulating member 18 interposed therebetween.

With such a configuration, the heat from the exhaust gas is transferred to the transducer stack 14 through the exhaust pipe 2, the housing 32a and the insulating member 18. More specifically, the housing 32a receives the heat from the exhaust gas at the outer surface of the first wall part 32a1 opposite to the inner surface of the first wall part 32a1. Each thermoelectric transducer 12 of the transducer stack 14 receives heat from the inner surface of the first wall part 32a1 through the insulating member 18 and from the inner surface of the second wall part 32a2 through the insulating member 18. In short, in the present embodiment, again based on the same concept as in the first embodiment, each thermoelectric transducer 12 is installed with the intrinsic semiconductor part 12c in contact with the heat supply surface (surface of the insulating member 18). Heat can therefore be supplied to the intrinsic semiconductor part 12c of each thermoelectric transducer 12 from two directions (the first wall part 32a1 and the second wall part 32a2).

In the present embodiment, the housing 32a (wall parts 32a1 and 32a2) and the insulating member 18 that are interposed between each thermoelectric transducer 12 and the exhaust pipe 2 correspond to the “intermediate member” according to the present disclosure. Moreover, the surfaces of the insulating members 18 that are located on the side of the thermoelectric transducer 12 and are in contact with the first wall part 32a1 and the second wall part 32a2 correspond to the “heat supply surfaces” (more specifically, a “first heat supply surface” and a “second heat supply surface”) according to the present disclosure. Further, the portions of the surface of the intrinsic semiconductor part 12c that are in contact with the surfaces of the insulating members 18 corresponding to the first and second heat supply surfaces correspond to a “first portion” and a “second portion” according to the present disclosure, respectively.

Next, an advantage of the method of installing the thermoelectric transducer (transducer stack) according to the present embodiment will be described. FIGS. 11A and 11B are diagrams for illustrating an advantage of the method of installing the thermoelectric transducer 12 according to the second embodiment by focusing on an individual thermoelectric transducer 12. FIG. 11B shows the thermoelectric transducer installed in a method other than the method according to the present disclosure when the thermoelectric transducer receives heat from two directions (from the first and second wall parts). In the example of the installation method shown in FIG. 11B, the surface of the intrinsic semiconductor part is not in contact with any of the two heat supply surfaces in the two directions, and the end faces of the n-type semiconductor part and the p-type semiconductor part having the highest band gap energy are in contact with the respective opposed heat supply surfaces. With this configuration, more heat is supplied to the n-type semiconductor part and the p-type semiconductor part than to the intrinsic semiconductor part.

FIG. 11A shows the thermoelectric transducer 12 installed in the method according to the present embodiment, as with the configuration shown in FIGS. 8 to 10. With the configuration according to the present embodiment, as shown in FIG. 11A, heat can be reliably supplied to the intrinsic semiconductor part 12c through the insulating members 18 from both of the first wall part 32a1 and the second wall part 32a2. Compared with the configuration according to the first embodiment in which heat is supplied in one direction, heat can be more uniformly input to each thermoelectric transducer 12.

FIGS. 12A and 12B are diagrams for illustrating an advantage of the manner of stacking of the thermoelectric transducers 12 according to the second embodiment. FIG. 12B shows examples of the manlier of stacking of the thermoelectric transducers that is possible when heat is supplied in two directions. The manner of stacking of the thermoelectric transducers in these examples is the same as that shown in FIG. 7B. In both of the left and right configurations according to the stacking manner shown in FIG. 12B, the surfaces of the intrinsic semiconductor parts of the two thermoelectric transducers closest to the first and second wall parts of the housing are in direct contact with the two heat supply surfaces.

FIG. 12A shows the thermoelectric transducers 12 stacked in the manner according to the present embodiment, as with the configuration shown in FIGS. 8 to 10. According to this stacking manner, on the sides of the first and second wall parts 32a1 and 32a2, the surfaces of the intrinsic semiconductor part 12c of each thermoelectric transducer 12 of the transducer stack 14 are in contact with different portions of the respective heat supply surfaces. As a result, the intrinsic semiconductor part 12c of each individual thermoelectric transducer 12 can receive an approximately equal heat flux from the two heat supply surfaces.

In the stacking manner according to the present embodiment shown in FIG. 12A, the electrode 16 electrically connects the parts having the highest band gap energy to each other. Therefore, even when heat is supplied in two directions, the electromotive voltage can be efficiently provided, and heat can be reliably input to each intrinsic semiconductor part 12c.

With the power generator 30 according to the present embodiment, main components for thermoelectric power generation are modularized as described below. That is, the power generator 30 has the thermoelectric transducer module 32 that includes the transducer stack 14 that is a stack of a plurality of thermoelectric transducers 12 and the housing 32a which not only serves to house and protect the transducer stack 14 but also serves as an intermediate member for transferring heat from the exhaust pipe 2 to the transducer stack 14. With the power generator 30, thermoelectric power generation using the thermoelectric transducers 12 can be achieved simply by installing the thermoelectric transducer module 32 on the exhaust pipe 2 and forming the electrical circuit 20.

In the transducer stack 14 in the thermoelectric transducer module 32, the thermoelectric transducers 12 are stacked in a serpentine form along the first wall part 32a1 of the housing 32a installed to conform to the outer surface of the exhaust pipe 2. When the thermoelectric transducers 12 are stacked in this manner, placing the thermoelectric transducer module 32 in such a manner that the first wall part 32a1 is in conformity to the outer surface of the exhaust pipe 2 (or the second wall part 32a2 is in conformity to the outer surface of the exhaust pipe 2) as described above is favorable because an adequate area of the housing 32a can be used for heat transfer from the exhaust pipe 2. However, the stacking pattern of the thermoelectric transducers 12 is not limited to this pattern, and any stacking pattern is possible as far as it meets the requirement that at least a portion of the surface of the intrinsic semiconductor part 12c of each thermoelectric transducer 12 is in contact with the “heat supply surface”. The shape of the housing for the transducer stack differs depending on the stacking pattern. The orientation of the thermoelectric transducer module with respect to the exhaust pipe 2 can be appropriately determined from the viewpoint of efficiency of heat transfer to the transducer stack depending on the stacking pattern and the shape of the housing.

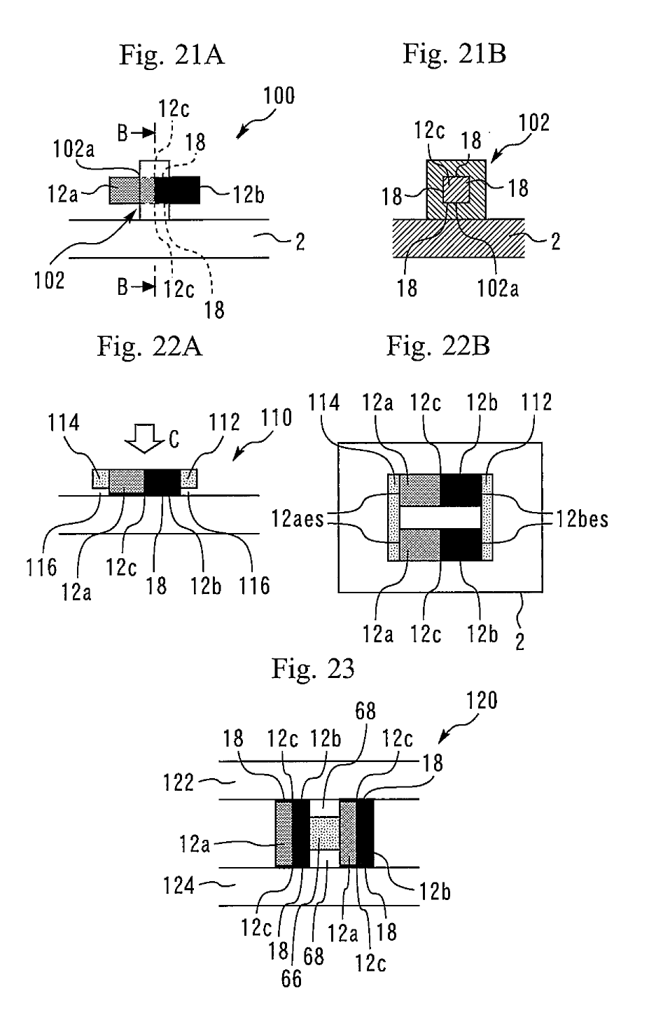

In this second embodiment, an example has been described in which each thermoelectric transducer 12 receives heat from two heat supply surfaces (in two directions). However, according to the present disclosure, the surface of the intrinsic semiconductor part of the thermoelectric transducer can be in contact with three or more heat supply surfaces. For example, in a configuration in which thermoelectric transducers having the shape of a rectangular parallelepiped are stacked to form a transducer stack having the shape of a rod, and the rod-shaped transducer stack is housed in a housing having the shape of a rectangular parallelepiped, three or four of the four inner side surfaces of the housing may be in contact with the surface of the intrinsic semiconductor part. The configuration in which the four inner side surfaces (that is, all the side surfaces) are used as heat supply surfaces corresponds to a configuration in which the whole of the surface of the intrinsic semiconductor part is in contact with the heat supply surface, as shown in FIG. 21 described later.

In this second embodiment, an example has been described in which the heat supply surfaces for all the thermoelectric transducers 12 forming the transducer stack 14 are the surfaces of the insulating members 18 on the side of the thermoelectric transducers 12. However, the heat supply surfaces for only some of the plurality of thermoelectric transducers forming the transducer stack housed in the housing of the thermoelectric transducer module according to the present disclosure may be the surfaces of the insulating members on the side of the thermoelectric transducers. In an arrangement that requires no insulating member between the housing and the thermoelectric transducers, the heat supply surfaces for at least some of the plurality of thermoelectric transducers forming the transducer stack may be the inner surface of the housing. This holds true for transducer stacks 42 and 64 described later.

### Third Embodiment

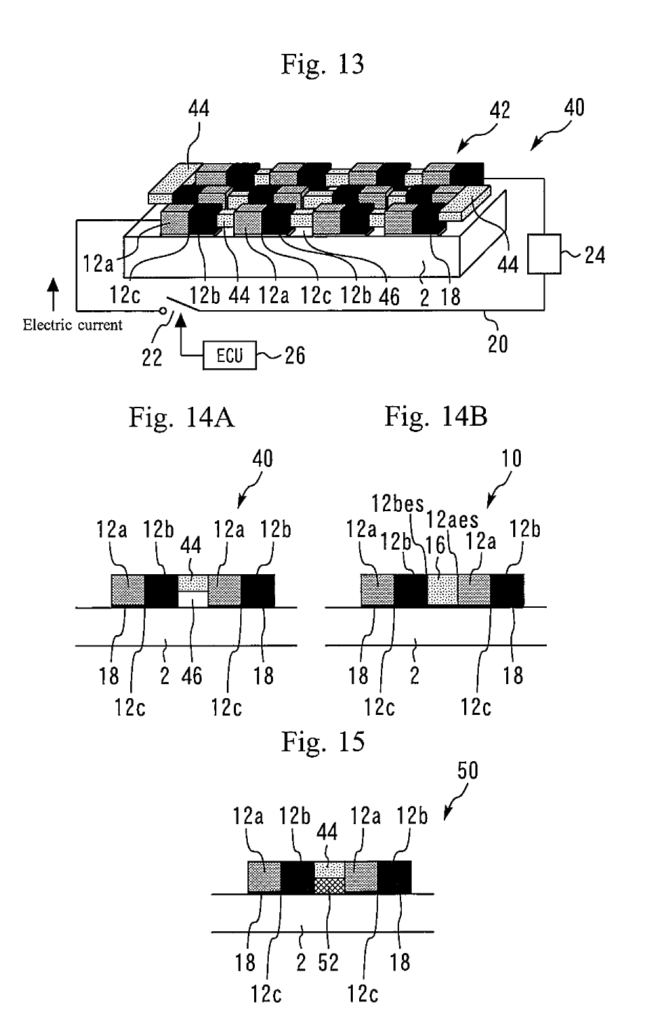

Next, with reference to FIGS. 13 and 14, a third embodiment of the present disclosure will be described.

FIG. 13 is a schematic perspective view showing an overall configuration of a power generator 40 for a vehicle according to the third embodiment of the present disclosure. The power generator 40 according to the present embodiment includes a transducer stack 42. A plurality of thermoelectric transducers 12 forming the transducer stack 42 are connected in series with each other with an electrode 44 interposed between every adjacent two of the thermoelectric transducers 12, as shown in FIG. 13. The stacking pattern of the transducer stack 42 is the same as that of the transducer stack 14 according to the first embodiment, for example. The power generator 40 differs from the power generator 10 according to the first embodiment in arrangement of the electrodes 44. The following description will be focused on the difference.

As shown in FIG. 13, each electrode 44 that connects two thermoelectric transducers 12 to each other is disposed not to be in contact with any of the exhaust pipe serving as the heat supplier that supplies heat to the transducer stack 42 and the insulating member 18 serving as the intermediate member that transfers the heat. In other words, there is an air layer 46 between the surface of the electrode 44 and the surface of the exhaust pipe 2 (heat supply surface).

FIGS. 14A and 14B are diagrams for illustrating an advantage of the arrangement of the electrodes 44 according to the third embodiment. FIG. 14B shows the arrangement of the electrode 16 according to the first embodiment. In this arrangement, the surface of the electrode 16 is in direct contact with the surface of the insulating member 18 serving as the heat supply surface. The electrode 16 made of metal basically has a higher thermal conductivity than the thermoelectric transducer 12. Therefore, with the arrangement shown in FIG. 14B, the electrode 16 has a stronger tendency to receive heat than the thermoelectric transducer 12. As a result, the heat supplied to the electrode 16 through the insulating member 18 is easily transferred to the parts of the thermoelectric transducer 12 that are in contact with the electrode 16 (that is, the end faces 12aes and 12bes of the n-type semiconductor part 12a and the p-type semiconductor part 12b having the highest band gap energy).

On the other hand, in the arrangement according to the present embodiment shown in FIG. 14A, there is the air layer 46 between the surface of the electrode 44 and the surface of the exhaust pipe 2, and the surface of the electrode 44 is not in contact with the surface of the exhaust pipe 2. With such an arrangement, heat is transferred through the air layer 46 from the surface of the exhaust pipe 2 (heat supply surface) to the surface of the electrode 44 on the side of the exhaust pipe 2. Thus, the heat flux received by the surface of the electrode 44 from the surface of the exhaust pipe 2 in this heat transfer is lower than the heat flux received by the surface of the intrinsic semiconductor part 12c of the thermoelectric transducer 12 via heat conduction from the surface of the insulating member 18 (heat supply surface). As a result, heat input from the electrode 44 to the n-type semiconductor part 12a and the p-type semiconductor part 12b can be reduced. As a result, a temperature difference is less likely to be produced in such a manner that the temperature of the n-type semiconductor part 12a or the p-type semiconductor part 12b having a relatively high band gap energy is higher than the temperature of the intrinsic semiconductor part 12c. Thus, efficient power generation can be achieved.

### Fourth Embodiment

Next, with reference to FIG. 15, a fourth embodiment of the present disclosure will be described. In the third embodiment described above, the power generator 40 has the air layer 46 between the surface of the electrode 44 and the surface of the exhaust pipe 2 (heat supply surface). However, according to the present disclosure, the specific arrangement for reducing the heat flux received by the surface of the electrode on the side of the heat supply surface compared with the heat flux received by the surface of the intrinsic semiconductor part 12c of the thermoelectric transducer from the heat supply surface is not limited to the arrangement in the example described above, and the arrangement described below with reference to FIG. 15 is also possible, for example.

FIG. 15 is a diagram for illustrating an arrangement of the electrode 44 in a power generator 50 for a vehicle according to the fourth embodiment of the present disclosure. In the power generator 50 shown in FIG. 15, instead of the air layer 46, a heat insulator 52 (which corresponds to a “heat insulator” according to the present disclosure) is disposed between the surface of the electrode 44 and the surface of the exhaust pipe 2 (heat supply surface). More specifically, the heat insulator 52 is made of a material (such as ceramics) that has a lower thermal conductivity than that of the electrode 44. The arrangement using the heat insulator 52 can also reduce the heat transfer from the exhaust pipe 2 to the electrode 44. As a result, the temperature difference in the manner described above is less likely to be produced, and efficient power generation can be achieved. The heat insulator 52 may be a separate member attached to the surface of the electrode 44 or a coating layer applied to the surface of the electrode 44, for example.

### Fifth Embodiment

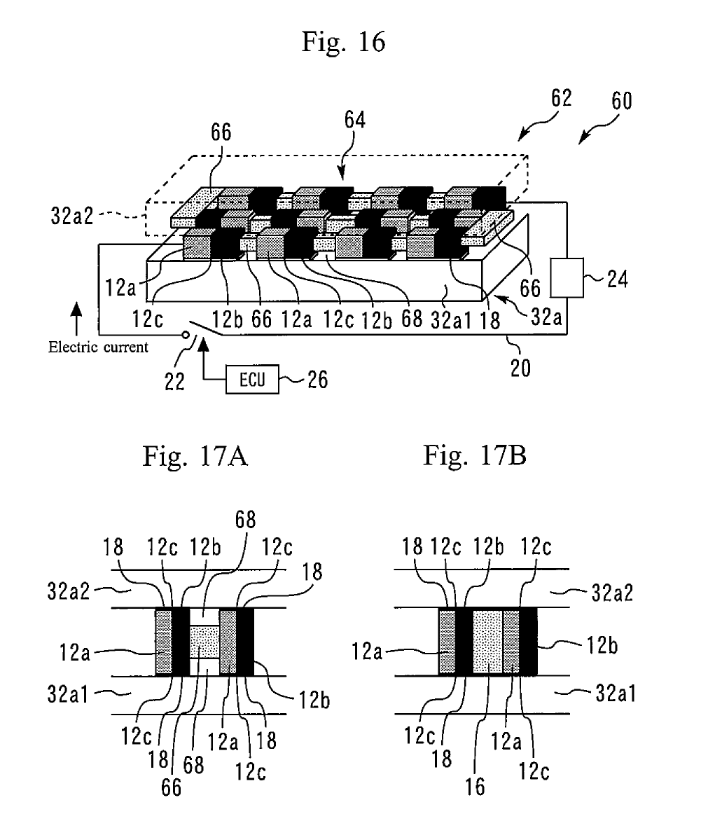

Next, with reference to FIGS. 16 and 17, a fifth embodiment of the present disclosure will be described.

FIG. 16 is a schematic diagram showing an overall configuration of a power generator 60 for a vehicle according to the fifth embodiment of the present disclosure. The power generator 60 according to the present embodiment is provided with a thermoelectric transducer module 62. The thermoelectric transducer module 62 includes a transducer stack 64 and the housing 32a described above with regard to the second embodiment. The plurality of thermoelectric transducers 12 forming the transducer stack 64 are connected in series with each other with an electrode 66 interposed between every adjacent two of the thermoelectric transducers 12, as shown in FIG. 16. The configuration of the transducer stack 64 is the same as the transducer stack 14 or 42 described above except for the arrangement of the electrode 66.

The arrangement of the electrode 66 according to the present embodiment is equivalent to the arrangement in which heat is supplied to each thermoelectric transducer 12 in two directions to which the same concept of the electrode 44 according to the third embodiment is additionally applied. That is, as shown in FIG. 16, each electrode 66 that connects two thermoelectric transducers 12 is disposed not to be in contact with any of the wall parts 32a1 and 32a2 of the housing 32a and the insulating member 18 that serve as the intermediate member for transferring heat to the transducer stack 64. In other words, an air layer 68 is provided between the surface of the electrode 66 and the surface of the first wall part 32a1 (heat supply surface) and between the surface of the electrode 66 and the surface of the second wall part 32a2 (heat supply surface).

FIGS. 17A and 17B are diagrams for illustrating an advantage of the arrangement of the electrode 66 according to the fifth embodiment. FIG. 17B shows the arrangement of the electrode 16 according to the second embodiment. In the arrangement shown in FIG. 17B, the electrode 16 is in direct contact with the surface of the insulating member 18 serving as the heat supply surface on both of the sides of the first wall part 32a1 and the second wall part 32a2.

On the other hand, in the arrangement according to the present embodiment shown in FIG. 17A, there is the air layer 68 between the surface of the electrode 66 and the surface of the first wall part 32a1 (heat supply surface) and between the surface of the electrode 66 and the surface of the second wall part 32a2 (heat supply surface), and the electrode 66 is not in contact with any of the wall parts 32a1 and 32a2. With such an arrangement, both on the sides of the first wall part 32a1 and the second wall part 32a2, the heat flux received by the surface of the electrode 66 from the surfaces of the wall parts 32a1 and 32a2 (heat supply surfaces) is lower than the heat flux received by the surface of the intrinsic semiconductor part 12c of the thermoelectric transducer 12 from the surface of the insulating member 18 (heat supply surface). As a result, heat input from the electrode 66 to the n-type semiconductor part 12a and the p-type semiconductor part 12b can be reduced, and efficient power generation can be achieved.

### Sixth Embodiment

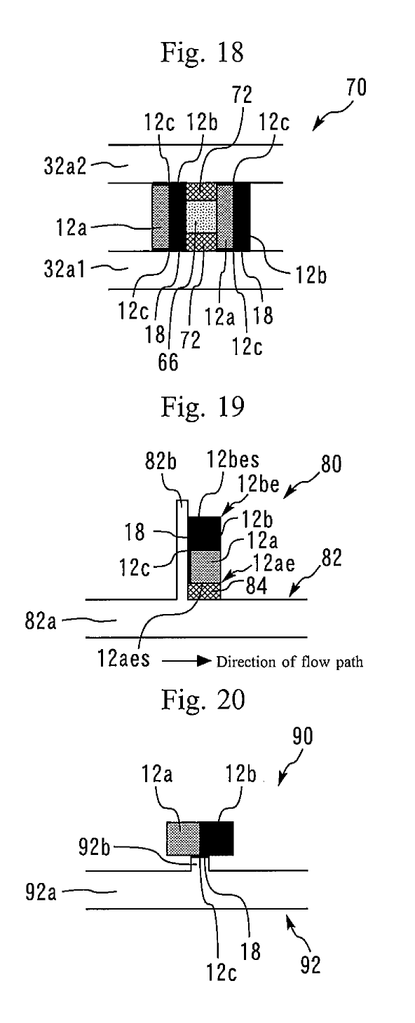

Next, with reference to FIG. 18, a sixth embodiment of the present disclosure will be described. As with the relation between the configuration according to the third embodiment shown in FIG. 14A and the configuration according to the fourth embodiment shown in FIG. 15, the configuration according to the fifth embodiment shown in FIG. 17A can be modified into the configuration shown in FIG. 18 described below.

FIG. 18 is a diagram for illustrating an arrangement of the electrode 66 in a power generator 70 for a vehicle according to the sixth embodiment of the present disclosure. In the power generator 70 shown in FIG. 18, instead of the air layer 68, a heat insulator 72 having the same configuration as the heat insulator 52 is disposed between the surface of the electrode 66 and the surface of the wall part 32a1 of the housing 32a (heat supply surface) and between the surface of the electrode 66 and the surface of the wall part 32a2 of the housing 32a (heat supply surface). The arrangement using the heat insulator 72 can also reduce the heat transfer from the wall parts 32a1 and 32a2 to the electrode 66. As a result, heat input from the electrode 66 to the n-type semiconductor part 12a and the p-type semiconductor part 12b can be suppressed, and efficient power generation can be achieved.

In the first to sixth embodiments described above, the power generator 10, 30, 40, 50, 60 or 70 is provided with the transducer stack 14, 42 or 64 formed by a plurality of thermoelectric transducers 12. However, the present disclosure is not necessarily limited to the power generators including a plurality of thermoelectric transducers in the form of a transducer stack, and the power generator according to the present disclosure may include only one thermoelectric transducer.

FIG. 19 is a diagram for illustrating another method of installing the thermoelectric transducer 12 shown in FIG. 2. An exhaust pipe 82 of a vehicle that incorporates a power generator 80 shown in FIG. 19 includes an exhaust pipe main part 82a. The exhaust pipe main part 82a has, on the outer surface thereof, a fin part 82b extending in a direction perpendicular to the direction of the flow path of the exhaust pipe 82. The thermoelectric transducer 12 of the power generator 80 is installed on the fin part 82b with the insulating member 18 interposed therebetween. In addition, a heat insulator 84 (which corresponds to the “heat insulator” according to the present disclosure) is interposed between the surface of the exhaust pipe main part 82a (heat supply surface) and the end portion 12ae (more specifically, the end face 12aes) of the n-type semiconductor part 12a. The heat insulator 84 is made of a material (such as ceramics) that has a lower thermal conductivity than that of the thermoelectric transducer 12. With such a configuration, although the end portion 12ae of the n-type semiconductor part 12a, that is, the part having the highest band gap energy, is disposed close to the heat supply surface, heat input to that part can be suppressed. As an alternative to the configuration shown in FIG. 19, the heat insulator 84 may be disposed between the end portion 12be of the p-type semiconductor part 12b and the heat supply surface. With any of the configuration shown in FIG. 19 and the alternative thereto, again, heat can be supplied to the thermoelectric transducer 12 while a temperature difference can be less likely to be produced in such a manner that the temperature of the n-type semiconductor part 12a and the p-type semiconductor part 12b having a relatively high band gap energy is higher than the temperature of the intrinsic semiconductor part 12c.

FIG. 20 is a diagram for illustrating another method of installing the thermoelectric transducer 12 shown in FIG. 2. An exhaust pipe 92 of a vehicle that incorporates a power generator 90 shown in FIG. 20 includes an exhaust pipe main part 92a. The exhaust pipe main part 92a has, on the outer surface thereof, a protrusion 92b protruding in a direction perpendicular to the direction of the flow path of the exhaust pipe 92. The thermoelectric transducer 12 of the power generator 90 is installed on the protrusion 92b with the insulating member 18 interposed therebetween. As shown in FIG. 20, the thermoelectric transducer 12 is not in contact with the heat supply surface (surface of the insulating member 18) at the whole of the side surface thereof on the side of the exhaust pipe 92 but only at the side surface of the intrinsic semiconductor part 12c and the side surface of a part of the thermoelectric transducer 12 close to the intrinsic semiconductor part 12c. With such a configuration, heat can be intensively input to the intrinsic semiconductor part 12c having a lower band gap energy than the n-type semiconductor part 12a and the p-type semiconductor part 12b. Thus, with this configuration, the temperature difference in the manner described above is less likely to occur. The protrusion 92b may be an intermediate member that is separated from the exhaust pipe 92 and transfers heat from the exhaust pipe 92 to the thermoelectric transducer 12. According to the present disclosure, any method of installing the thermoelectric transducer is possible including the example shown in FIG. 20, as far as it ensures that, of the surface of the thermoelectric transducer, at least a portion (one side surface, if the thermoelectric transducer has the shape of a prism, for example) of at least the surface of the intrinsic semiconductor part is in contact with the heat supply surface.

FIGS. 21A and 21B are diagrams for illustrating another method of installing the thermoelectric transducer 12 shown in FIG. 2. In a power generator 100 shown in FIG. 21A, the thermoelectric transducer 12 is installed on the exhaust pipe 2 with an intermediate member 102 and the insulating member 18 interposed therebetween. FIG. 21B is a cross-sectional view of the thermoelectric transducer 12 and the surrounding structure taken along the line B-B in FIG. 21A. As can be seen from these drawings, the thermoelectric transducer 12 is inserted into a through-hole 102a formed in the intermediate member 102, and the surface of the intrinsic semiconductor part 12c and a part of the thermoelectric transducer 12 close to the intrinsic semiconductor part 12c is covered with the intermediate member 102 with the insulating member 18 interposed therebetween. Inside the through-hole 102a, the whole of the side surface of the thermoelectric transducer 12 is in contact with the surface of the insulating member 18 (heat supply surface). That is, in this configuration, unlike the configurations in which only a portion of the surface of the intrinsic semiconductor part 12c is in contact with the heat supply surface, such as the configuration shown in FIG. 5, the whole of the surface of the intrinsic semiconductor part 12c is in contact with the surface of the insulating member 18 (heat supply surface). According to this configuration, heat from the exhaust gas is supplied from the exhaust pipe 2 to the thermoelectric transducer 12 through the intermediate member 102 and the insulating member 18. With such a configuration, again, heat can be intensively input to the intrinsic semiconductor part 12c having a relatively low band gap energy.

FIGS. 22A and 22B are diagrams for illustrating another manner of stacking of the thermoelectric transducers 12 shown in FIG. 2. In a power generator 110 shown in FIG. 22A, again, each thermoelectric transducer 12 is installed on the exhaust pipe 2 with the insulating member 18 interposed therebetween. Of course, as in the other examples, each thermoelectric transducer 12 is disposed with the intrinsic semiconductor part 12c in contact with the heat supply surface (surface of the insulating member 18).

FIG. 22B is a plan view of the thermoelectric transducer 12 viewed in the direction of the arrow C in FIG. 22A. As can be seen from these drawings, end faces 12bes of the p-type semiconductor parts 12b serving as a positive electrode of adjacent thermoelectric transducers 12 (which correspond to the “first thermoelectric transducer” and the “second thermoelectric transducer” according to the present disclosure) are electrically connected to each other by an electrode 112 (which corresponds to a “positive electrode” according to the present disclosure), and end faces 12aes of the n-type semiconductor part 12a serving as a negative electrode of the adjacent thermoelectric transducers 12 are electrically connected to each other by an electrode 114 (which corresponds to a “negative electrode” according to the present disclosure). The transducer stack of a plurality of thermoelectric transducers 12 is not limited to the stack including the thermoelectric transducers 12 connected in series with each other, such as those in the examples described above, and a stack including the thermoelectric transducers 12 connected in parallel with each other, such as the configuration shown in FIGS. 22A and 22B, is also possible. As an alternative, the transducer stack according to the present disclosure may be a combination of a series connection of a plurality of thermoelectric transducers 12 and a parallel connection of a plurality of thermoelectric transducers 12. In addition, the combination may not be on a thermoelectric transducer basis. For example, a plurality of thermoelectric transducers are connected in series with each other to form a transducer stack that provides a desired electromotive voltage, and a plurality of thermoelectric transducer modules each including such a transducer stack may be connected in parallel with each other.

Furthermore, in the configuration shown in FIGS. 22A and 22B, as with the configuration according to the third embodiment, an air layer 116 is provided between the surface of the electrode 114 on the side of the exhaust pipe 2 and the surface of the exhaust pipe 2 (heat supply surface). As an alternative, as with the configuration according to the fourth embodiment, the heat insulator 52 may be disposed between the surface of the electrode 114 on the side of the exhaust pipe 2 and the surface of the exhaust pipe 2 (heat supply surface).

FIG. 23 is a diagram for illustrating another method of installing the thermoelectric transducer 12 shown in FIG. 2. In a power generator 120 shown in FIG. 23, each thermoelectric transducer 12 is supplied with heat from two heat suppliers of a vehicle, more specifically, a housing of a battery 122 and a cooling water hose 124. With such a configuration, the intrinsic semiconductor part 12c of each thermoelectric transducer 12 is in contact with the surface of the battery 122 and the surface of the cooling water hose 124 (that is, the heat supply surfaces of the two heat suppliers). The housing of the battery 122 is made of resin, and the cooling water hose 124 is made of rubber. That is, these heat suppliers are made of materials having high insulating properties. Thus, this configuration corresponds to an example in which there is no insulating member 18 serving as the intermediate member, and the surface of the heat supplier serves as the heat supply surface with which the thermoelectric transducer 12 is in contact.

According to the present disclosure, as an alternative to the two heat suppliers in the example shown in FIG. 23, three or more heat suppliers may be used to supply heat to a thermoelectric transducer. Furthermore, in the configuration shown in FIG. 23, the heat source of the housing of the battery 122 is the battery 122 itself, and the heat source of the cooling water hose is the engine cooling water (from the internal combustion engine 1). The plurality of heat suppliers according to the present disclosure do not have to have different heat sources as in the configuration of the example shown in FIG. 23, and a plurality of heat suppliers that share the same heat source (engine cooling water), such as a radiator and the cooling water hose, can also be used.

The embodiments and modifications described above may be combined in other ways than those explicitly described above as required and may be modified in various ways without departing from the scope of the present disclosure.

What is claimed is:

1. A power generator for a vehicle, comprising:
a thermoelectric transducer including an n-type semiconductor part, a p-type semiconductor part, and an intrinsic semiconductor part disposed between the n-type semiconductor part and the p-type semiconductor part, a band gap energy of the intrinsic semiconductor part being lower than each band gap energy of the n-type semiconductor part and the p-type semiconductor part,
wherein the power generator is used in a vehicle that includes a heat supplier configured to supply heat to the thermoelectric transducer,
wherein the thermoelectric transducer is supplied with heat from a heat supply surface, which is a surface of the heat supplier or a surface of an intermediate member between the thermoelectric transducer and the heat supplier, and
wherein the thermoelectric transducer is installed in such a manner that at least a portion of a surface of at least the intrinsic semiconductor part of a surface of the thermoelectric transducer is in contact with the heat supply surface.

2. The power generator according to claim 1,
wherein the thermoelectric transducer includes a first thermoelectric transducer and a second thermoelectric transducer,
wherein the power generator further comprises an electrode that electrically connects the first thermoelectric transducer and the second thermoelectric transducer to each other,
wherein at least a portion of the surface of at least the intrinsic semiconductor part of the surface of the first thermoelectric transducer is in contact with a first portion of the heat supply surface, and
wherein at least a portion of the surface of at least the intrinsic semiconductor part of the surface of the second thermoelectric transducer is in contact with a second portion of the heat supply surface, which is different from the first portion.

3. The power generator according to claim 2,
wherein the electrode connects an end portion of the n-type semiconductor part of the first thermoelectric transducer on a side opposite to the intrinsic semiconductor part and an end portion of the p-type semiconductor part of the second thermoelectric transducer on a side opposite to the intrinsic semiconductor part.

4. The power generator according to claim 2,
wherein the electrode includes:
a positive electrode that connects an end portion of the n-type semiconductor part of the first thermoelectric transducer on a side opposite to the intrinsic semiconductor part and an end portion of the n-type semiconductor part of the second thermoelectric transducer on a side opposite to the intrinsic semiconductor part to each other; and
a negative electrode that connects an end portion of the p-type semiconductor part of the first thermoelectric transducer on a side opposite to the intrinsic semiconductor part and an end portion of the p-type semiconductor part of the second thermoelectric transducer on a side opposite to the intrinsic semiconductor part to each other.

5. The power generator according to claim 3,
wherein the power generator is configured so that a heat flux received from the heat supply surface by a surface of the electrode on a side of the heat supply surface is lower than a heat flux received from the heat supply surface by a surface of the intrinsic semiconductor part of each of the first thermoelectric transducer and the second thermoelectric transducer.

6. The power generator according to claim 5,
wherein the electrode is installed to face the heat supply surface with an air layer interposed therebetween.

7. The power generator according to claim 5, further comprising a heat insulator interposed between the surface of the electrode and the heat supply surface.

8. The power generator according to claim 1, further comprising a heat insulator installed between the heat supply surface and an end portion of the n-type semiconductor part of the thermoelectric transducer on a side opposite to the intrinsic semiconductor part or an end portion of the p-type semiconductor part of the thermoelectric transducer on a side opposite to the intrinsic semiconductor part.

9. The power generator according to claim 1,
wherein the thermoelectric transducer includes a plurality of thermoelectric transducers,
wherein the power generator comprises the plurality of thermoelectric transducers in a form of a thermoelectric transducer module,
wherein the thermoelectric transducer module includes a transducer stack formed by the plurality of thermoelectric transducers electrically connected to each other and a housing that houses the transducer stack,
wherein the housing serves as the intermediate member, or the housing and an insulating member interposed between the housing and the plurality of thermoelectric transducers serve as the intermediate member, and
wherein the heat supply surface for at least some of the plurality of thermoelectric transducers forming the transducer stack is an inner surface of the housing or a surface of the insulating member on a side of the plurality of thermoelectric transducers.

10. The power generator according to claim 9,
wherein the thermoelectric transducer module is installed in such a manner that an outer surface of the housing opposite to the inner surface of the housing is in contact with the surface of the heat supplier.

11. The power generator according to claim 1,
wherein the heat supply surfaces includes a first heat supply surface and a second heat supply surface, and
wherein, of the surface of the thermoelectric transducer, a first portion of the surface of the intrinsic semiconductor part is in contact with the first heat supply surface, and a second portion of the surface of the intrinsic semiconductor part is in contact with the second heat supply surface.

12. The power generator according to claim 1,
wherein the heat supplier includes a plurality of heat suppliers, and
wherein at least a portion of the surface of at least the intrinsic semiconductor part of the surface of the thermoelectric transducer is in contact with the heat supply surface of each of the plurality of heat suppliers.

13. The power generator according to claim 1,
wherein the heat supplier is an exhaust pipe of an internal combustion engine mounted on the vehicle.

14. The power generator according to claim 12,
wherein one of the plurality of heat suppliers is an exhaust pipe of an internal combustion engine mounted on the vehicle.
